(19) United States
(12) Patent Application Publication
(10) Pub. No.: US 2010/0096616 A1
(43) Pub. Date: Apr. 22, 2010

(54) LIGHT-EMITTING AND LIGHT-DETECTING OPTOELECTRONIC DEVICE

(75) Inventors: SHIH-CHENG HUANG, Hukou (TW); PO-MIN TU, Hukou (TW)

Correspondence Address: PCE INDUSTRY, INC.;ATT. Steven Reiss, 288 SOUTH MAYO AVENUE, CITY OF INDUSTRY, CA, 91789, US

(73) Assignee: ADVANCED OPTOELECTRONIC TECHNOLOGY, INC., Hsinchu Hsien (TW)

(21) Appl. No.: 12/550,764

(22) Filed: Aug. 31, 2009

(30) Foreign Application Priority Data
Oct. 21, 2008 (CN) 200810305081.0

(51) Int. Cl. H01L 33/00; H01L 31/0352

(52) U.S. Cl. 257/13; 257/21; 257/E33.008; 257/E31.033

(57) ABSTRACT

An exemplary optoelectronic device includes a substrate and an epitaxial structure formed on the optoelectronic device. The epitaxial structure includes an N-type semiconductor layer, a P-type semiconductor layer, a multi-quantum-well layer and an undoped semiconductor layer. The multi-quantum-well layer is arranged between the N-type semiconductor layer and the P-type semiconductor layer. The undoped semiconductor layer is sandwiched between the N-type semiconductor layer and the multi-quantum-well layer. The undoped semiconductor layer is represented by a general formula AlᵣInₛGa₁₋ᵣ₋ₛN, wherein r≧0, s≧0, and 1≧r+s≧0. A barrier energy level of the undoped semiconductor layer is larger than a barrier energy level of the multi-quantum-well layer.

### BACKGROUND

1. Technical Field

The present disclosure generally relates to optoelectronics and, particularly, to an optoelectronic device capable of both emitting light and detecting light.

2. Discussion of Related Art

Optoelectronics is the study and application of electronic devices that source, detect and control light, and is usually considered a sub-field of photonics. Optoelectronic devices are electrical-to-optical devices, such as light emitting diodes (LEDs), or optical-to-electrical devices, such as photodetectors. Optoelectronics is based on the quantum mechanical effects of light on semiconducting materials, sometimes in the presence of electric fields. Gallium nitride-based (GaN-based) semiconductors can be used as light emitting elements of LEDs or as light absorbing elements of photodetectors.

In an LED having GaN-based semiconductors, when the LED is forward biased (switched on), electrons are able to recombine with holes in the GaN-based semiconductor structure and energy is released in the form of light. This effect is called electroluminescence, and the color of the light is determined by the energy gap of the semiconductor structure. In a GaN-based semiconductor structure, wavelengths of the light emitted from the LED are in the range from 200 nanometers (nm) to 1.5 microns (μm).

In a photodetector having GaN-based semiconductors, when the GaN-based semiconductor structure is irradiated by light of certain wavelengths and is reverse biased, electrons and holes can be generated in the GaN-based semiconductor structure. Thereby, a photocurrent is generated through the photodetector and is measured, and the light is detected. The wavelengths of the light may range from 200 nm to 1.5 μm.

The GaN-based semiconductor structure of the LED and the GaN-based semiconductor structure of the photodetector are somewhat different. Thus GaN-based semiconductors in LEDs generally cannot be used in photodetectors, and vice versa.

Therefore, what is needed is an optoelectronic device that can overcome the above-described shortcomings.

### BRIEF DESCRIPTION OF THE DRAWINGS

Many aspects of the present optoelectronic device can be better understood with reference to the following drawings. The components in the drawings are not necessarily drawn to scale, the emphasis instead being placed upon clearly illustrating the principles of the present optoelectronic device. Moreover, in the drawings, all the views are schematic, and like reference numerals designate corresponding parts throughout the several views.

FIG. 1 is a cross-sectional view of a semiconductor structure of an optoelectronic device in accordance with a first exemplary embodiment.

FIG. 2 shows energy levels of layers of the semiconductor structure of FIG. 1.

FIG. 3 is a cross-sectional view of a semiconductor structure of an optoelectronic device in accordance with a second exemplary embodiment.

FIG. 4 shows energy levels of layers of the semiconductor structure of FIG. 3.

FIG. 5 is a cross-sectional view of a semiconductor structure of an optoelectronic device in accordance with a third exemplary embodiment.

### DETAILED DESCRIPTION

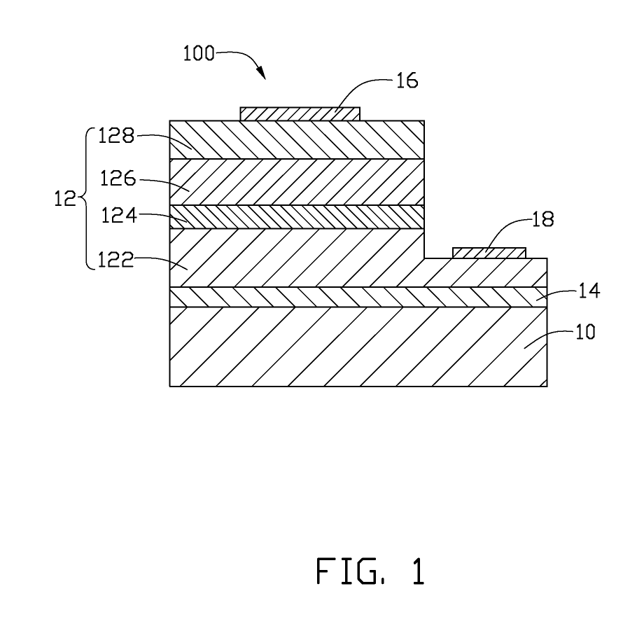

Referring to FIG. 1, an optoelectronic device 100 in accordance with a first exemplary embodiment is shown. The optoelectronic device 100 includes a substrate 10, an epitaxial structure 12, and a buffer layer 14 sandwiched between the substrate 10 and the epitaxial structure 12.

A material of the substrate 10 can be selected from the group consisting of sapphire, GaN, copper-tungsten, silicon, silicon carbide (SiC), and aluminum nitride (AlN). The buffer layer 14 is epitaxially grown on the substrate 10. In this embodiment, the buffer layer 14 is a GaN buffer layer. The buffer layer 14 can be formed on the substrate 10 by a metal-organic chemical vapor deposition (MOCVD) method. The buffer layer 14 is configured for adjusting lattice mismatch between the substrate 10 and the epitaxial structure 12 grown on the buffer layer 14.

The epitaxial structure 12 includes an N-type semiconductor layer 122, an undoped semiconductor layer 124, a multi-quantum-well (MQW) layer 126, and a P-type semiconductor layer 128 sequentially stacked one on another in the above order. The N-type semiconductor layer 122 is formed on the buffer layer 14. These stacked layers 122, 124, 126 and 128 can be grown through the MOCVD method.

The N-type semiconductor layer 122 can be represented by a general formula AlₐIn_{b}Ga_{1-a-b}N, wherein a≧0, b≧0, and 1≧a+b≧0. The N-type semiconductor layer 122 is a semiconductor doped with a material, such as Si, for providing electrons. For example, the N-type semiconductor layer 122 may be selected from the group consisting of N-type GaN, N-type InGaN, N-type AlGaN, and N-type Al_{0.25}In_{0.25}Ga_{0.5}N.

The P-type semiconductor layer 128 is represented by a general formula Al_{c}In_{d}Ga_{1-c-d}N, wherein c≧0, d≧0, and 1≧c+d≧0. The P-type semiconductor layer 122 is a semiconductor doped with a material, such as Mg, for providing holes. For example, the P-type semiconductor layer 128 may be selected from the group consisting of P-type GaN, P-type InGaN, P-type AlGaN, and P-type Al_{0.25}In_{0.25}Ga_{0.5}N.

The MQW layer 126 includes a number of semiconductor sub-layers stacked alternately. In particular, a plurality of first semiconductor sub-layers and a plurality of second semiconductor sub-layers are alternately laminated one on the other. Each of the first and second semiconductor sub-layers can be represented by a general formula AlₓIn_{y}Ga_{1-x-y}N, wherein x≧0, y≧0, and 1≧x+y≧0. For example, the sub-layers of the MQW layer 126 can include GaN layers and In_{y}Ga_{1-y}N layers alternately stacked. That is, the sub-layers are stacked in the following order: GaN/In_{y}Ga_{1-y}N/GaN/In_{y}Ga_{1-y}N/GaN . . . The MQW layer 126 functions as an active layer of the optoelectronic device 100.

The undoped semiconductor layer 124 can be represented by a general formula AlᵣInₛGa₁₋ᵣ₋ₛN, wherein r≧0, s≧0, and 1≧r+s≧0. An energy level of the undoped semiconductor layer 124 can be changed by changing the values of the variables r and s in the formula AlᵣInₛGa₁₋ᵣ₋ₛN.

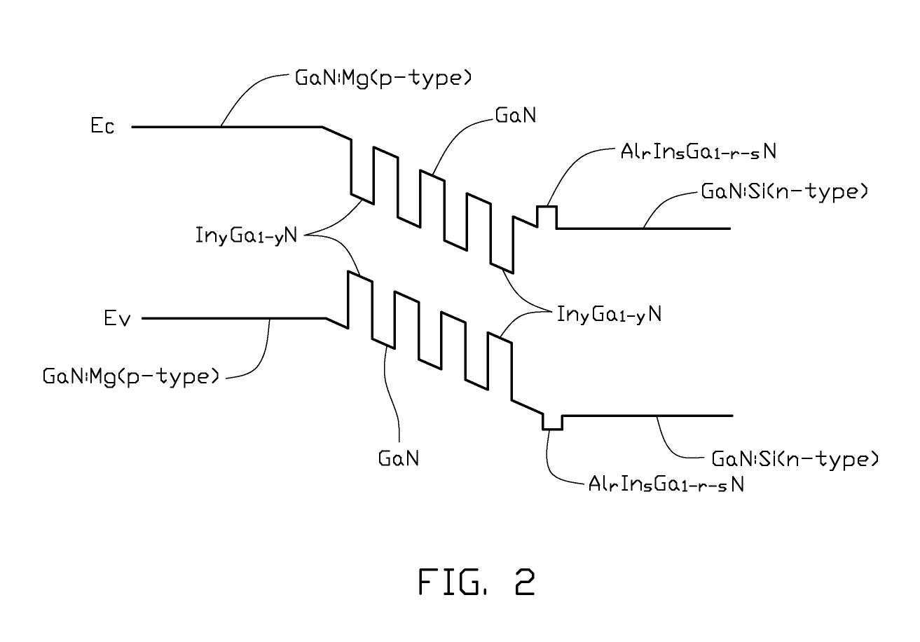

Referring to FIG. 2, energy levels of each layer of the optoelectronic device 100 are shown. Ec represents the conduction band energy level of the optoelectronic device 100. Ev represents the valence band energy level of the optoelectronic device 100. The energy level of the undoped semiconductor layer 124 is a barrier energy level. The barrier energy level of the undoped semiconductor layer 124 is larger than an energy level of the N-type semiconductor layer 122. The energy level of the undoped semiconductor layer 124 is also larger than a barrier energy level of the MQW layer 126, such that a dark current generated in the optoelectronic device 100 when the optoelectronic device 100 is reverse biased can be reduced. Thus, a photocurrent in the optoelectronic device 100 can be measured more easily.

The ratio of the photocurrent and the dark current in the optoelectronic device 100 when the optoelectronic device 100 is reverse biased can be changed by changing a molar content Mc of the Al in the AlᵣInₛGa₁₋ᵣ₋ₛN of the undoped semiconductor layer 124. When the molar content Mc of the Al in AlᵣInₛGa₁₋ᵣ₋ₛN is less than 5%, the undoped semiconductor layer 124 may have such a low barrier energy that the dark current cannot be reduced efficiently. When the molar content Mc of the Al in AlᵣInₛGa₁₋ᵣ₋ₛN is greater than 20%, the undoped semiconductor layer 124 may have such a high barrier energy that the photocurrent may be reduced. Therefore, the molar content Mc of the undoped semiconductor layer 124 is preferably in the range: 5%≦Mc≦20%.

A thickness Tn of the undoped semiconductor layer 124 may affect the performance thereof. When the thickness Tn of the undoped semiconductor layer 124 is less than 1 nanometer (nm), an electrical current may easily break down the undoped semiconductor layer 124 (this is called the tunneling effect). Most of the electrons will flow through the breakdown area of the undoped semiconductor layer 124, and thus the performance of the undoped semiconductor layer 124 is reduced or even completely nullified. When the thickness Tn of the undoped semiconductor layer 124 is greater than 50 nm, the resistance of the undoped semiconductor layer 124 is increased and the photocurrent is reduced, thereby resulting in difficulty measuring the photocurrent. Therefore, the thickness Tn of the undoped semiconductor layer 124 is preferably in the range: 1 nm≦Tn≦50 nm.

The optoelectronic device 100 further includes a first electrode 16 and a second electrode 18. The first electrode 16 is formed on the P-type semiconductor layer 128. Portions of the undoped semiconductor layer 124, the MQW layer 126 and the P-type semiconductor layer 128 are removed by etching to expose the N-type semiconductor layer 122. The second electrode 18 is formed on the N-type semiconductor layer 122. In the illustrated embodiment, the N-type semiconductor layer 122 is stepped, and the second electrode 18 is formed on a lower step of the N-type semiconductor layer 122. A material of the first and second electrodes 16 and 18 can include metal or an alloy, for example titanium (Ti), aluminum (Al), nickel (Ni), platinum (Pt), chromium (Cr), copper (Cu) or an alloy of at least two of these metals. The material of the first and second electrodes 16 and 18 can instead include light-pervious conductive materials, for example indium tin oxide (ITO) or indium zinc oxide (IZO). The first and second electrodes 16 and 18 are configured for electrically connecting to an electrical source.

In this embodiment, the optoelectronic device 100 can function as both a light emitting element and a photodetector. When the optoelectronic device 100 is forward biased, the optoelectronic device 100 functions as a light emitting element, such as an LED. When the optoelectronic device 100 is reverse biased, the optoelectronic device 100 functions as a photodetector for measuring a photocurrent of light transmitting through the optoelectronic device 100. Because the dark current is reduced by the undoped semiconductor layer 124, values of the photocurrent can be read more accurately.

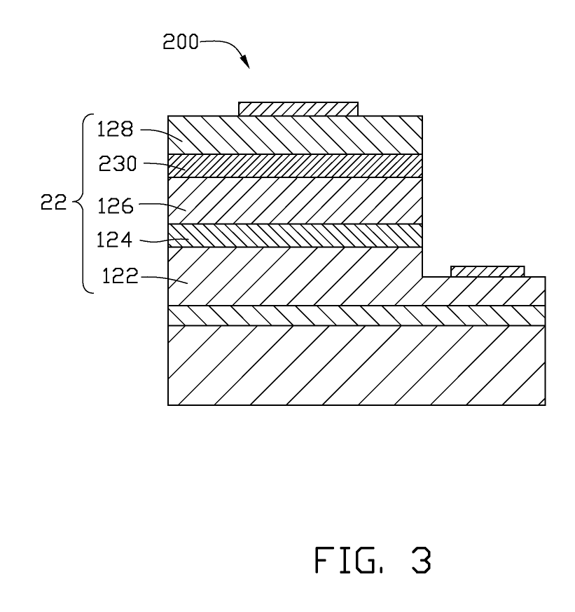

Referring to FIG. 3, an optoelectronic device 200 in accordance with a second exemplary embodiment is shown. The optoelectronic device 200 is similar to the optoelectronic device 100. The distinguishing feature is that an epitaxial structure 22 of the optoelectronic device 200 further includes a second P-type semiconductor layer 230 sandwiched between the P-type semiconductor layer 128 and the MQW layer 126.

The second P-type semiconductor layer 230 can be represented by a general formula Al_{w}Ga_{1-w}N, wherein 1>w≧0. The second P-type semiconductor layer 230 functions as an electron blocking layer, i.e., a confinement layer.

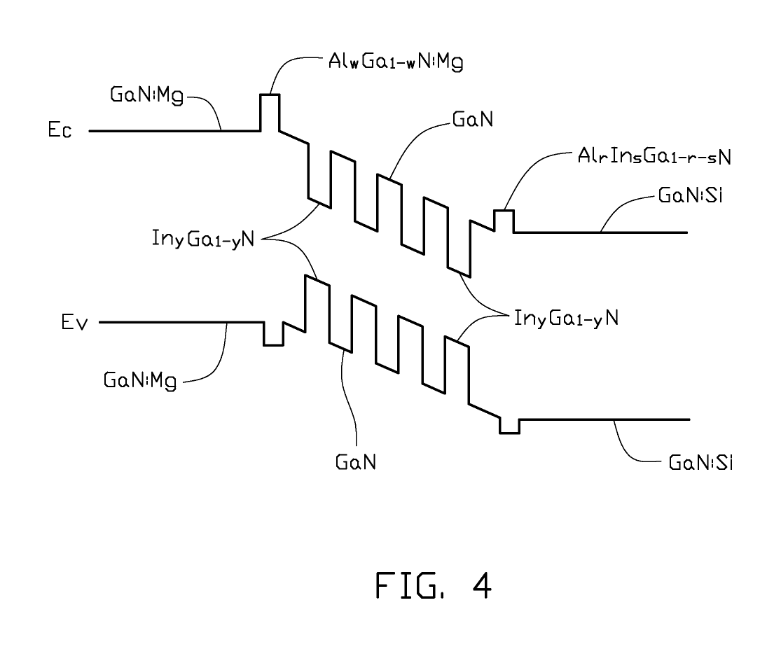

As shown in FIG. 4, the second P-type semiconductor layer 230 has an energy level higher than that of the MQW layer 126. Therefore, the second P-type semiconductor layer 230 is capable of blocking electrons escaping from the MQW layer 126 when the optoelectronic device 200 is forward biased. That is, electron-hole recombination is confined in the MQW layer 126 for emitting light when the optoelectronic device 200 functions as a light emitting element. Thus a light emitting efficiency of the optoelectronic device 200 is improved.

In this embodiment, the dark current is reduced by the undoped semiconductor layer 124, therefore, values of the photocurrent can be read more accurately. The optoelectronic device 200 can also function as both a light emitting element when the optoelectronic device 200 is forward biased and a photodetector when the optoelectronic device 200 is reverse biased because of the effect of the undoped semiconductor layer 124.

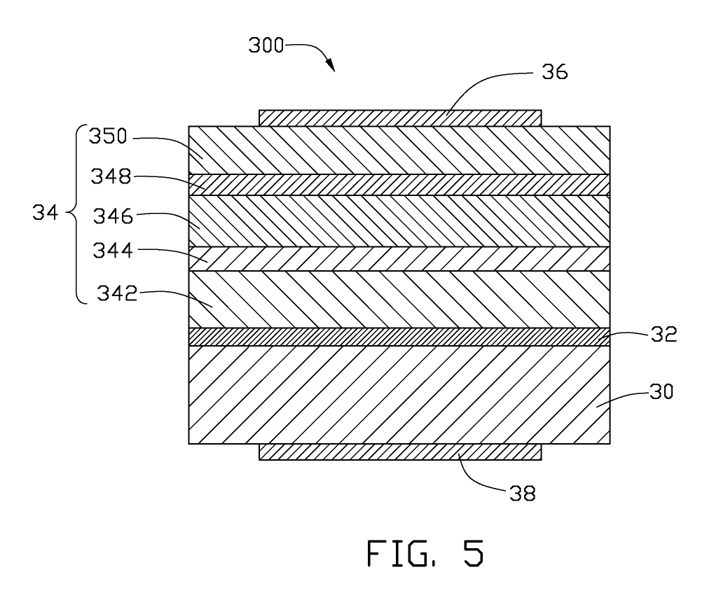

Referring to FIG. 5, an optoelectronic device 300 in accordance with a third exemplary embodiment is shown. The optoelectronic device 300 includes an electrically conductive substrate 30, a reflective layer 32, and an epitaxial structure 34 sequentially stacked one on another in the above order. The epitaxial structure 34 is similar to the epitaxial structure 22 of the optoelectronic device 200 of the second exemplary embodiment. The epitaxial structure 34 includes a first P-type semiconductor layer 342, a second P-type semiconductor layer 344, an MQW layer 346, an undoped semiconductor layer 348, and an N-type semiconductor layer 350 sequentially stacked one on another in the above order, wherein the first P-type semiconductor layer 342 is stacked on the reflective layer 32. A first electrode 36 is formed on the N-type semiconductor layer 350. A second electrode 38 is formed on an underside of the electrically conductive substrate 30.

A material of the reflective layer 32 can be selected from the group consisting of platinum, silver, aluminum, and other metals with high reflectivity. In the present embodiment, the reflective layer 32 is formed on an underside of the first P-type semiconductor layer 342. The reflective layer 32 is configured for reflecting light in the optoelectronic device 300. When the optoelectronic device 300 is forward biased, the reflective layer 32 reflects the light generated in the MQW layer 346. Thereby, more light is transmitted through the N-type semiconductor layer 350 to the exterior, thus obtaining output light with higher brightness. When the optoelectronic device 300 is reverse biased, the optoelectronic device 300 functions as a photodetector. Exterior light is transmitted through the epitaxial structure 34 and reflected by the reflective layer 32 back to the MQW layer 346. Thereby, more light is absorbed and detected by the MQW layer 346, thus increasing the detecting accuracy of the optoelectronic device 300.

The electrically conductive substrate 30 can include at least one of copper, copper-tungsten, silicon, silicon carbide, aluminum, etc. The electrically conductive substrate 30 is formed on the reflective layer 32 by a eutectic process. The electrically conductive substrate 30 can also have high heat conductivity, so that heat generated in the MQW layer 346 can be conducted out from the optoelectronic device 300 via the electrically conductive substrate 30. The electrically conductive substrate 30 can also enhance the mechanical strength of the optoelectronic device 300, thereby helping prevent the optoelectronic device 300 from being bent or damaged.

Finally, it is to be understood that the above-described embodiments are intended to illustrate rather than limit the disclosure. Variations may be made to the embodiments without departing from the spirit of the disclosure. The above-described embodiments illustrate the scope of the disclosure but do not restrict the scope of the disclosure.

What is claimed is:

1. A light-emitting and light-detecting optoelectronic device, comprising:
a substrate;
an epitaxial structure generally on the substrate, the epitaxial structure comprising:
an N-type semiconductor layer represented by a general formula AlₐIn_{b}Ga_{1-a-b}N, wherein a≧0, b≧0, and 1≧a+b≧0,
a first P-type semiconductor layer, represented by a general formula Al_{c}In_{d}Ga_{1-c-d}N, wherein c≧0, d≧0, and 1≧c+d≧0,
a multi-quantum-well layer between the N-type semiconductor layer and the first P-type semiconductor layer, the multi-quantum-well layer being represented by a general formula AlₓIn_{y}Ga_{1-x-y}N, wherein x≧0, y≧0 and 1≧x+y≧0, and
an undoped semiconductor layer sandwiched between the N-type semiconductor layer and the multi-quantum-well layer, the undoped semiconductor layer being represented by a general formula AlᵣInₛGa₁₋ᵣ₋ₛN, wherein r≧0, s≧0, and 1≧r+s≧0, a barrier energy level of the undoped semiconductor layer being larger than a barrier energy level of the multi-quantum-well layer.

2. The optoelectronic device of claim 1, wherein a thickness Tn of the undoped semiconductor layer is in the range of: 1 nm≦Tn≦50 nm.

3. The optoelectronic device of claim 1, wherein the N-type semiconductor layer is generally on the substrate, and the first P-type semiconductor layer is at an opposite side of the N-type semiconductor layer away from the substrate.

4. The optoelectronic device of claim 3, further comprising a second P-type semiconductor layer sandwiched between the first P-type semiconductor layer and the multi-quantum-well layer, the second P-type semiconductor layer being represented by a general formula Al_{w}Ga_{1-w}N, wherein 1>w≧0.

5. The optoelectronic device of claim 3, wherein a material of the substrate is selected from the group consisting of sapphire, gallium nitride (GaN), copper-tungsten, silicon, silicon carbide (SiC) and aluminum nitride.

6. The optoelectronic device of claim 3, further comprising a buffer layer between the N-type semiconductor layer and the substrate.

7. The optoelectronic device of claim 6, further comprising a first electrode and a second electrode, wherein the N-type semiconductor layer comprises an exposed step portion, the first electrode is formed on the first P-type semiconductor layer, and the second electrode is formed on the exposed step portion of the N-type semiconductor layer.

8. The optoelectronic device of claim 4, further comprising a buffer layer between the N-type semiconductor layer and the substrate.

9. The optoelectronic device of claim 8, further comprising a first electrode and a second electrode, wherein the N-type semiconductor layer comprises an exposed step portion, the first electrode is formed on the first P-type semiconductor layer, and the second electrode is formed on the exposed step portion of the N-type semiconductor layer.

10. The optoelectronic device of claim 1, wherein the first P-type semiconductor layer is generally on the substrate, and the N-type semiconductor layer is at an opposite side of the first P-type semiconductor layer away from the substrate.

11. The optoelectronic device of claim 10, further comprising a reflective layer between the substrate and the first P-type semiconductor layer.

12. The optoelectronic device of claim 11, wherein a material of the reflective layer is selected from the group consisting of platinum, silver and aluminum.

13. The optoelectronic device of claim 10, wherein the substrate is electrically conductive.

14. The optoelectronic device of claim 11, further comprising a first electrode formed on the N-type semiconductor layer, and a second electrode formed on an underside of the substrate.

15. The optoelectronic device of claim 13, wherein a material of the substrate is selected from the group consisting of copper, copper-tungsten, and aluminum.

16. The optoelectronic device of claim 10, wherein the epitaxial structure further comprises a second P-type semiconductor layer between the first P-type semiconductor layer and the multi-quantum-well layer, the second P-type semiconductor layer being represented by a general formula Al_{w}Ga_{1-w}N, wherein 1>w≧0.

17. A light-emitting and light-detecting optoelectronic device, comprising:
an N-type semiconductor layer;
a first P-type semiconductor layer;
a multi-quantum-well layer between the N-type semiconductor layer and the first P-type semiconductor layer; and
an undoped semiconductor layer sandwiched between the N-type semiconductor layer and the multi-quantum-well layer, a barrier energy level of the undoped semiconductor layer being larger than a barrier energy level of the multi-quantum-well layer.

18. The optoelectronic device of claim 17, wherein each of the N-type semiconductor layer, the first type semiconductor layer, the multi-quantum-well layer and the undoped semiconductor layer is represented by a general formula AlₐIn_{b}Ga_{1-a-b}N, wherein a≧0, b≧0, and 1≧a+b≧0.

19. The optoelectronic device of claim 17, further comprising a second P-type semiconductor layer sandwiched between the first P-type semiconductor layer and the multi-quantum-well layer.

20. The optoelectronic device of claim 19, wherein the second P-type semiconductor layer is represented by a general formula Al_{w}Ga_{1-w}N, wherein 1>w≧0.
